(19) United States
(12) Patent Application Publication
(10) Pub. No.: US 2024/0329164 A1
(43) Pub. Date: Oct. 3, 2024

(54) HALL SENSOR WITH MAGNETIC FLUX CONCENTRATOR

(71) Applicant: TEXAS INSTRUMENTS INCORPORATED, Dallas, TX (US)

(72) Inventors: Dok Won Lee, Mountain View, CA (US); Keith Ryan Green, Prosper, TX (US); Fanping Sui, Plano, TX (US); Charles Parkhurst, Murphy, TX (US)

(21) Appl. No.: 18/193,099

(22) Filed: Mar. 30, 2023

(51) Int. Cl. G01R 33/07; G01R 33/00; H10N 52/01; H10N 52/80

(52) U.S. Cl. CPC G01R 33/077; G01R 33/0011; H10N 52/01; H10N 52/80

(57) ABSTRACT

The present disclosure generally relates to magnetic field sensors with magnetic flux concentrators, and more particularly, to Hall sensors (which may be vertical or in-plane field Hall sensors) with magnetic flux concentrators. In an example, a sensor device includes a semiconductor die, a first magnetic flux concentrator, and a second magnetic flux concentrator. The semiconductor die includes a semiconductor substrate and an interconnect structure. The semiconductor substrate includes a Hall sensor in a semiconductor material. The interconnect structure is over the semiconductor substrate. The first magnetic flux concentrator is over the semiconductor die. The second magnetic flux concentrator is over the semiconductor die. At least part of the Hall sensor is laterally between the first magnetic flux concentrator and the second magnetic flux concentrator.

### BACKGROUND

Various types of sensors have been developed to detect the presence of a magnetic field. A Hall sensor is one type of sensor that may be used to detect the presence and measure the magnitude of a magnetic field. The output voltage of a Hall sensor may be proportional to the magnetic field strength through the Hall sensor. Hall sensors may be used for proximity sensing, positioning, speed detection, and current sensing applications.

### SUMMARY

This Summary is provided to introduce a brief selection of disclosed concepts in a simplified form that are further described below in the Detailed Description including the drawings provided. Various disclosed devices and methods may be beneficially applied to an integrated circuit (IC) die (e.g., in a packaged device) that includes a Hall sensor (which may be a vertical or in-plane field Hall sensor). While such examples may be expected to have increased sensitivity for sensing a magnetic field, no particular result is a requirement unless explicitly recited in a particular claim.

An example described herein is a sensor device. The sensor device includes a semiconductor die, a first magnetic flux concentrator, and a second magnetic flux concentrator. The semiconductor die includes a semiconductor substrate and an interconnect structure. The semiconductor substrate includes a Hall sensor in a semiconductor material. The interconnect structure is over the semiconductor substrate. The first magnetic flux concentrator is over the semiconductor die. The second magnetic flux concentrator is over the semiconductor die. At least part of the Hall sensor is laterally between the first magnetic flux concentrator and the second magnetic flux concentrator.

Another example is an integrated circuit. The integrated circuit includes a semiconductor die, a first magnetic flux concentrator, a second magnetic flux concentrator, and a molding compound. The semiconductor die includes a Hall sensor. The first magnetic flux concentrator is on the semiconductor die. The second magnetic flux concentrator is on the semiconductor die. At least part of the Hall sensor is laterally between the first magnetic flux concentrator and the second magnetic flux concentrator. The molding compound encapsulates the semiconductor die, the first magnetic flux concentrator, and the second magnetic flux concentrator.

A further example is a method of fabricating an integrated circuit. A first magnetic flux concentrator is formed on a semiconductor die including a Hall sensor. A second magnetic flux concentrator is formed on the semiconductor die. At least part of the Hall sensor is laterally between the first magnetic flux concentrator and the second magnetic flux concentrator. The semiconductor die and the first and second magnetic flux concentrators are packaged to form an integrated circuit.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

The same reference numbers or other reference designators are used in the drawings to designate the same or similar (functionally and/or structurally) features.

FIG. 1 is a schematic illustrating a partial cross-sectional view of a sensor device according to some examples.

FIG. 2 is a schematic illustrating a cross-sectional view of an internal component of the sensor device of FIG. 1 according to some examples.

FIG. 3 is a schematic illustrating a plan view of an internal component of the sensor device of FIG. 1 according to some examples.

FIGS. 4A and 4B are schematics illustrating a plan view and a cross-sectional view, respectively, of a magnetic flux profile through the sensor device of FIG. 1 according to some examples.

FIG. 5 is a schematic illustrating cross-sectional view of a packaged integrated circuit including the sensor device of FIG. 1 according to some examples.

FIG. 6 is a flowchart of a method of fabricating a packaged integrated circuit including a sensor device, according to some examples.

FIGS. 7, 8, 9, 10, 11, and 12 are schematics illustrating partial cross-sectional views of the sensor device during the fabrication operations of FIG. 6 according to some examples.

FIG. 13 is a plan view of a sensor device according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and may be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to magnetic field sensors with magnetic flux concentrators, and more particularly, to Hall sensors (which may be vertical or in-plane field Hall sensors) with magnetic flux concentrators. In various examples, magnetic flux concentrators (MFCs) are on or supported by an semiconductor die, and the semiconductor die includes a Hall sensor. The Hall sensor is laterally between the MFCs, and the MFCs are arranged or configured to concentrate a magnetic field through the Hall sensor. The MFCs may be formed over a protective dielectric layer of the semiconductor die. The MFCs being formed at such a level may permit the MFCs to be formed with a greater thickness. The MFCs having a greater thickness may permit the MFCs to concentrate a larger magnetic field through the Hall sensor, which may effectively increase the sensitivity of the Hall sensor. Other advantages and benefits may be achieved in various examples.

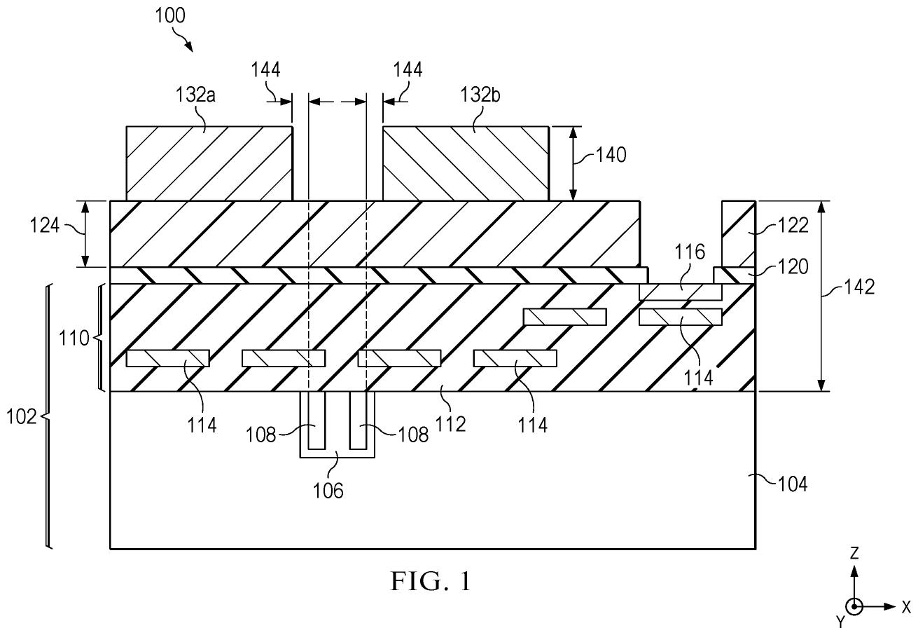

FIG. 1 is a cross-sectional view of a sensor device 100 including an semiconductor die 102 with MFCs 132a and 132b thereover according to some examples. Sensor device 100 can be part of a packaged integrated circuit. FIG. 1 shows x-y-z coordinate axes to aid in orienting FIG. 1 and subsequent figures. The cross-sectional of FIG. 1 is in an x-z plane.

The semiconductor die 102 includes a semiconductor substrate 104. The semiconductor substrate 104 includes a Hall sensor 106, and the Hall sensor 106 includes multiple active sensor sub-elements 108. Although not illustrated, the Hall sensor 106 may include non-active, or dummy, sensor sub-elements, such as at lateral boundaries of the Hall sensor 106. In some examples, the dummy sensor sub-elements generally are not electrically connected to the active sensor sub-elements 108. In some examples, signals output by the dummy sensor sub-elements are not included (or scaled with a lower weight) in the magnetic field measurement output by the sensor device 100.

The semiconductor substrate 104 may be or include a bulk semiconductor substrate, a semiconductor-on-insulator (SOI) substrate, or other semiconductor substrate, and in some cases, may include one or more epitaxial layer epitaxially grown on an underlying substrate. In some examples, the semiconductor substrate 104 is or includes a bulk silicon substrate (e.g., singulated from a wafer), which may further include one or more silicon epitaxial layers epitaxially grown on the bulk silicon substrate. The Hall sensor 106 may be a vertical or in-plane field Hall sensor, in some examples. A Hall sensor 106 may be configured to detect the presence of a magnetic field in or proximate to the semiconductor die 102. For example, the Hall sensor 106 may be configured to detect an in-plane (e.g., parallel to a top surface of the semiconductor substrate 104) magnetic field. The Hall sensor 106 includes four active sensor sub-elements 108, as described subsequently. In other examples, the Hall sensor 106 may include a different number of active sensor sub-elements 108. While an example Hall sensor 106 is described in more detail subsequently, any type or configuration of a Hall sensor or other magnetic sensor may be implemented.

The semiconductor die 102 further includes an interconnect structure 110 on or over the semiconductor substrate 104. The interconnect structure 110 includes one or more dielectric layers 112 and one or more interconnect metal layers 114 embedded in or surrounded by the dielectric layer(s) 112. The one or more dielectric layers 112 may include a pre-metal dielectric (PMD) layer, one or more inter-metal dielectric (IMD) layers, one or more etch stop layers (ESLs), the like, or a combination thereof. Each dielectric layer 112 may be or include any dielectric to provide electrical insulation (or reduced electrical conductivity), such as silicon oxide, borophosphosilicate glass (BPSG), phosphosilicate glass (PSG), silicon nitride, silicon oxynitride, silicon oxycarbon nitride, silicon oxycarbide, or the like. Each interconnect metal layer 114 may include metal contacts, metal vias, and/or metal lines. The top-most interconnect metal layer 114 of the interconnect structure 110 includes a metal external connector bond pad 116. The metal external connector bond pad 116 of the top-most interconnect metal layer 114 may be configured to have attached thereto an external connector, such as a wire by wire bonding. Each interconnect metal layer 114 (e.g., metal contacts, metal vias, metal lines, and/or metal bond pads therein) may include one or more barrier and/or adhesion layers (e.g., titanium nitride (TiN), tantalum nitride (TaN), the like, or a combination thereof) and a fill metal (e.g., tungsten (W), copper (Cu), aluminum (Al), the like, or a combination thereof) on the one or more barrier and/or adhesion layer. The interconnect metal layers 114 may interconnect various devices formed in and/or on the semiconductor substrate 104, including the Hall sensor 106.

The semiconductor die 102 also includes a protective dielectric layer 120 over the interconnect structure 110. More specifically, the protective dielectric layer 120 is over the interconnect metal layer 114 that includes the metal external connector bond pad 116 (e.g., the top-most interconnect metal layer 114 of the interconnect structure 110). An opening through the protective dielectric layer 120 exposes the metal external connector bond pad 116. The protective dielectric layer 120 may be or include various dielectric materials, such as silicon oxide, silicon nitride, silicon oxynitride, or the like.

The packaged device 100 includes a polymer layer 122 over the protective dielectric layer 120. An opening through the polymer layer 122 generally corresponds with and aligns with the opening through the protective dielectric layer 120 that exposes the metal external connector bond pad 116. In some examples, the polymer layer 122 may be polyimide or the like. The polymer layer 122 has a thickness 124 (e.g., in a direction normal to the top surface of the semiconductor substrate 104). In some examples, the thickness 124 of the polymer layer 122 may be equal to or greater than 3 μm, such as in a range from 3 μm to 15 μm (e.g., 5 μm). In some examples, the polymer layer 122 may be omitted.

In the illustrated examples, the MFCs 132a, 132b are over or on the polymer layer 122. In other examples, such as when the polymer layer 122 is omitted, the MFCs 132a, 132b are over or on the protective dielectric layer 120. More generally, the MFCs 132a, 132b are over and supported by the semiconductor die 102. Further, the MFCs 132a, 132b are over and supported by a same surface of the semiconductor die 102 (e.g., the MFCs 132a, 132b are on a same side of the semiconductor die 102). The MFCs 132a, 132b include a magnetic material. For example, the MFCs 132a, 132b may each be or include cobalt, nickel, iron, a binary alloy thereof (e.g., nickel iron (NiFe) alloy), and/or a ternary alloy thereof. In some examples, each MFC 132a, 132b includes a single layer of magnetic material, and in other examples, one or both MFCs 132a, 132b may include layers of different magnetic materials.

The MFCs 132a, 132b have a thickness 140 (e.g., in a direction normal to the top surface of the semiconductor substrate 104). In some examples, the thickness 140 of the MFCs 132a, 132b may be equal to or greater than 10 μm, such as in a range from 10 μm to 50 μm, and more specifically, equal to or greater than 15 μm, such as in a range from 15 μm to 50 μm (e.g., 18 μm). The MFCs 132a, 132b are arranged with the interconnect structure 110, the protective dielectric layer 120, and the polymer layer 122 vertically (in the orientation of FIG. 1) between the Hall sensor 106 and the MFCs 132a, 132b. A distance 142 may be between the Hall sensor 106 (e.g., the top surface of the semiconductor substrate 104) and the MFCs 132a, 132b. The distance 142 may be the cumulative thicknesses of the interconnect structure 110, the protective dielectric layer 120, and, if present, the polymer layer 122. In some examples, the distance 142 may be equal to or greater than 5 μm, such as in a range from 5 μm to 100 μm.

In the illustrated example, each of the MFCs 132a, 132b is laterally offset from a nearest boundary of a respective nearest active sensor sub-element 108 of the Hall sensor 106 by a distance 144. The boundary of an active sensor sub-element 108 of the Hall sensor 106 may be an edge of an isolation region (e.g., a shallow trench isolation (STI)) that defines the active sensor sub-element 108 in the semiconductor substrate 104. Neither of the MFCs 132a, 132b vertically overlap with the Hall sensor 106 (e.g., no portion of either of the MFCs 132a, 132b is directly over and within the boundaries of the Hall sensor 106). When one or more dummy sensor sub-elements are present in the Hall sensor 106, the MFCs 132a, 132b may overlap, at least partially, respective dummy sensor sub-elements. In other examples, one or both of the MFCs 132a, 132b may have a sidewall that vertically aligns with a respective nearest boundary of a respective nearest active sensor sub-element 108 of the Hall sensor 106, and/or one or both the MFCs 132a, 132b may have a portion that vertically overlaps a respective portion of an active sensor sub-element 108 of the Hall sensor 106.

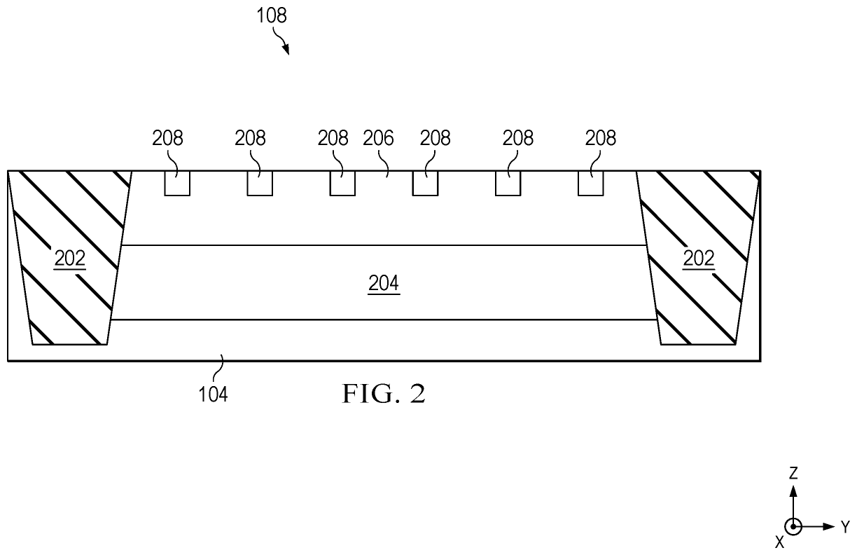

FIG. 2 is a cross-sectional view of an active sensor sub-element 108 in the semiconductor substrate 104 according to some examples. The cross-sectional of FIG. 2 is in a y-z plane, and hence, is perpendicular to the cross-sectional shown in FIG. 1. Each active sensor sub-element 108 of the Hall sensor 106 in FIG. 1 may be configured as the active sensor sub-element 108 shown in FIG. 2. The active sensor sub-element 108 of FIG. 2 is merely an example, and other active sensor sub-elements may be implemented in other examples. For example, the active sensor sub-element 108 of FIG. 2 may be referred to as a six contact, four terminal active sensor sub-element, and in different examples, the active sensor sub-element may be a five contact, four terminal active sensor sub-element or another active sensor sub-element.

Isolation regions 202 are in the semiconductor substrate 104 and laterally bound the active sensor sub-element 108. Each isolation region 202 extends from the top surface of the semiconductor substrate 104 to a depth in the semiconductor substrate 104. The isolation regions 202 may be or include silicon oxide or another dielectric material. In some examples, the isolation regions 202 are STIs, and in other examples, the isolation regions 202 may be another isolation region, such as a field oxide (FOX).

A doped buried layer 204 is in the semiconductor substrate 104, and a doped well 206 is in the semiconductor substrate 104 and over the doped buried layer 204. The doped buried layer 204 and the doped well 206 are laterally between the isolation regions 202. The doped buried layer 204 and the doped well 206 may be doped by a same conductivity type dopant. In some examples, the doped buried layer 204 and the doped well 206 are doped with n-type dopants, and the doped buried layer 204 may be an n-doped buried layer (NBL), and the doped well 206 may an n-doped well (NWell). In some examples, the doped buried layer 204 may be omitted. In some examples, another doped buried layer may be between the doped buried layer 204 and the doped well 206 and may be doped an opposite conductivity type (e.g., a p-type dopant) from the doped buried layer 204 and the doped well 206.

Doped well 206 can include doped regions 208. The doped regions extend from the top surface of the semiconductor substrate 104 to a depth in the semiconductor substrate 104 and in the doped well 206. In the illustrated example, the active sensor sub-element 108 includes six doped regions 208. In other examples, other numbers of doped regions 208 may be included in an active sensor sub-element 108. The doped regions 208 may be doped by a same conductivity type dopant as the doped buried layer 204 and the doped well 206. The doped regions 208 may be doped to a concentration that is greater than the dopant concentration of the doped well 206, which may be greater than the dopant concentration of the doped buried layer 204. For example, the doped regions 208, the doped well 206, and the doped buried layer 204 each may include n-type dopant (or n-dopant). In some examples, an n-dopant concentration of the doped regions 208 may be in a range from 1×10¹⁹ cm⁻³ to 1×10²¹ cm⁻³. In some examples, an n-dopant concentration of the doped well 206 may be in a range from 1×10¹⁶ cm⁻³ to 1×10¹⁸ cm⁻³. In some examples, an n-dopant concentration of the doped buried layer 204 may be in a range from 1×10¹⁸ cm⁻³ to 1×10²⁰ cm⁻³.

A dummy sensor sub-element may have similar structure as the active sensor sub-element 108 shown in FIG. 2. A dummy sensor sub-element may be formed along lateral boundaries of the Hall sensor 106 to reduce process variation in the active sensor sub-elements 108. The active sensor sub-elements 108 of the Hall sensor 106 may be electrically connected together (e.g., by connecting various highly doped regions 208 to the interconnect structure 110), whereas a dummy sensor sub-element generally is not electrically connected to the active sensor sub-elements 108.

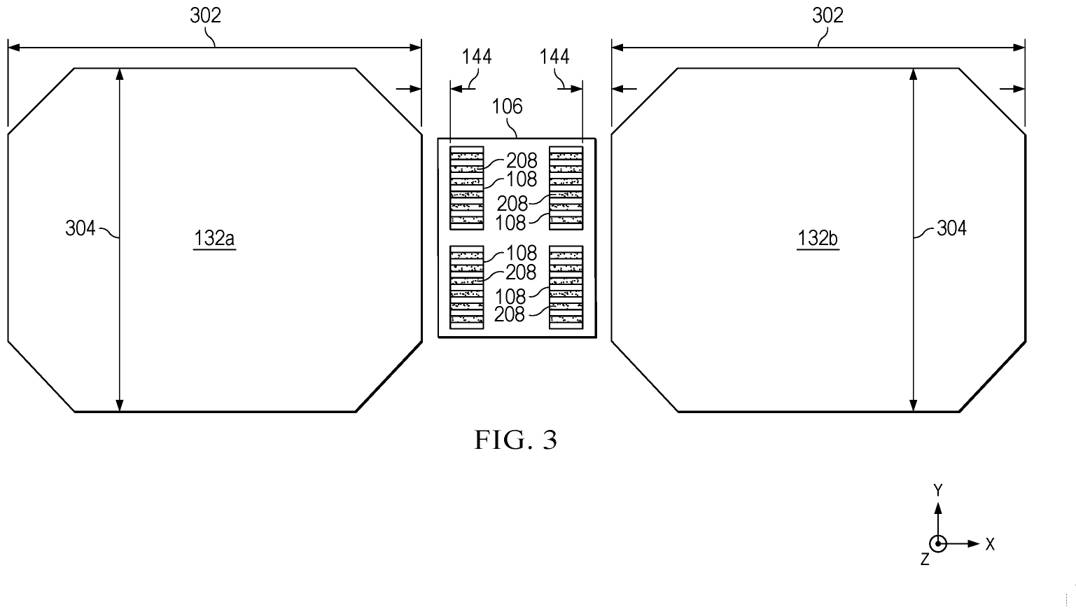

FIG. 3 is a plan view showing the MFCs 132a, 132b relative to the Hall sensor 106. The layout view of FIG. 3 is in an x-y plane. The Hall sensor 106 includes four active sensor sub-elements 108 arranged in an array (e.g., a 2×2 array). As shown, the Hall sensor 106 is laterally between the MFCs 132a, 132b. The MFCs 132a, 132b are each shown to have an octagonal shape in the x-y plane. In other examples, the MFCs 132a, 132b may have different lateral shapes, such as circle, rectangle, square, etc.

The distance 144 is laterally between the MFC 132a and a respective nearest boundary of a respective nearest active sensor sub-element 108 of the Hall sensor 106, and the distance 144 is laterally between the MFC 132b and a respective nearest boundary of a respective nearest active sensor sub-element 108 of the Hall sensor 106. The MFCs 132a, 132b are therefore configured to concentrate an in-plane (e.g., in an x-y plane) magnetic flux through the Hall sensor 106. As oriented, the MFCs 132a, 132b concentrate a magnetic flux along an x-direction, and the Hall sensor 106 senses a magnetic field that is along the x-direction.

Further, the MFCs 132a, 132b each have a first lateral dimension 302 along a first direction and a second lateral dimension 304 along a second direction. The first direction is perpendicular to the second direction. In the illustrated example, the first direction is along an x-direction, and the second direction is along a y-direction. In some examples, the first lateral dimension 302 may be in a range from 150 μm to 500 μm, and the second lateral dimension 304 may be in a range from 150 μm to 500 μm. Other lateral shapes, such as a circle, rectangle, square, etc., for the MFCs 132a, 132b may also have the first and/or second lateral dimensions 302, 304.

Although not illustrated, one or more dummy sensor sub-elements may be included in the Hall sensor 106 underlying the MFC 132a, and one or more dummy sensor sub-elements may be included in the Hall sensor 106 underlying the MFC 132b. For example, along an x-direction, there may be a pair of y-direction aligned dummy sensor sub-elements, a pair of y-direction aligned active sensor sub-elements 108, another pair of y-direction aligned active sensor sub-elements 108, and another pair of y-direction aligned dummy sensor sub-elements.

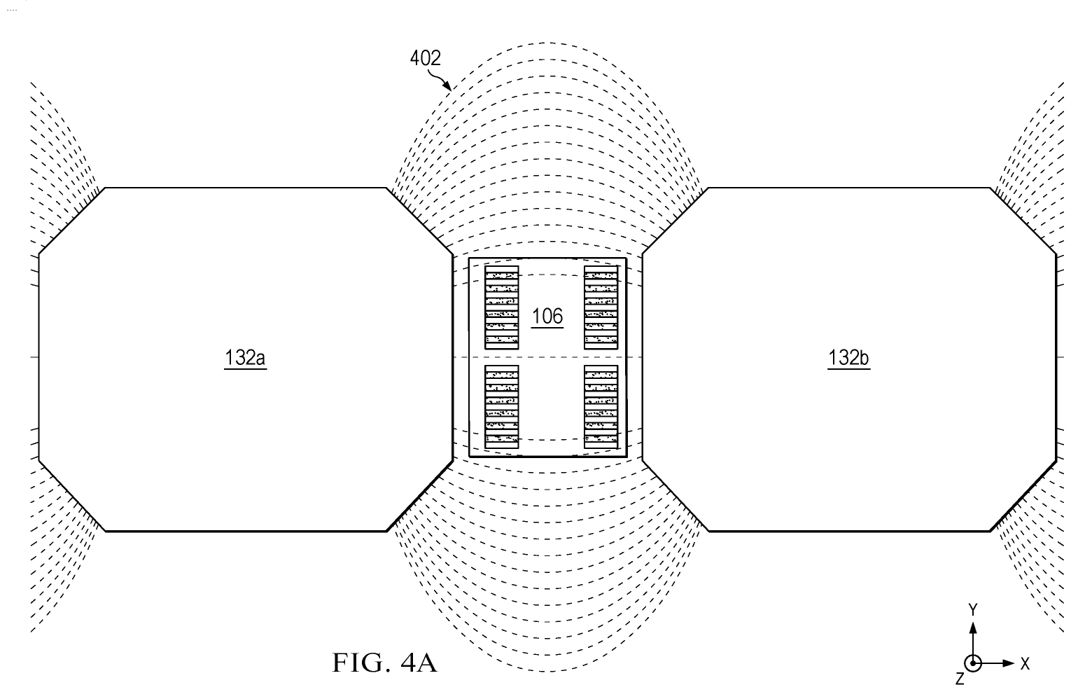

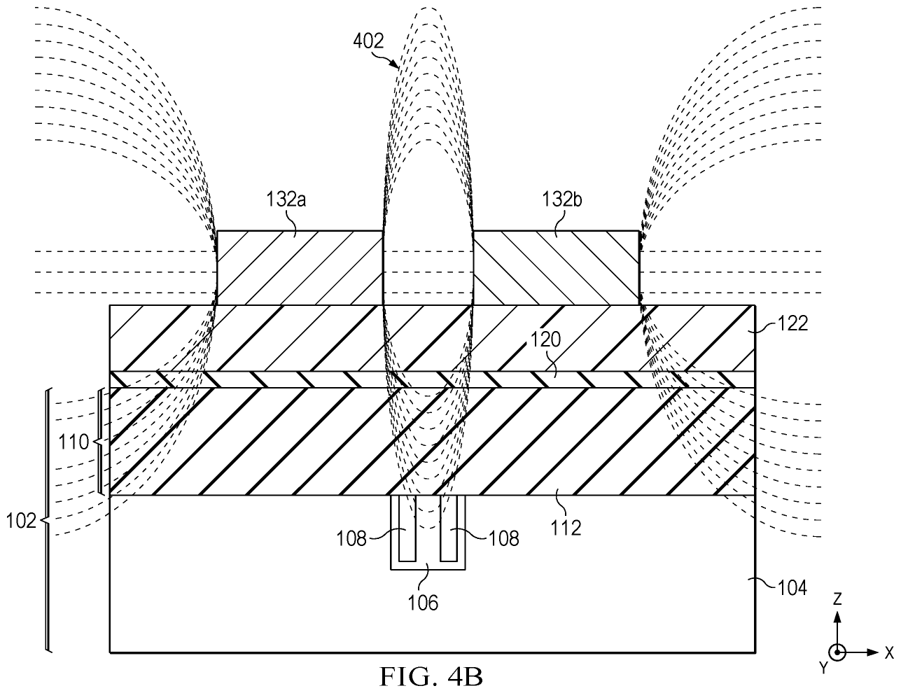

FIGS. 4A and 4B are a plan view and a cross-sectional view, respectively, that show a magnetic flux profile through the MFCs 132a, 132b according to some examples. Due to MFCs 132a and 312b, the magnetic flux vectors 402 have a relatively high intensity in an x-y plane laterally between the MFCs 132a, 132b, which can offset the additional distance 142 between the Hall sensor 106 and the MFCs 132a, 132b. The relatively high intensity magnetic flux vectors 402 incident upon the Hall sensor 106 in the semiconductor substrate 104 can improve the sensitivity of the Hall sensor 106.

Specifically, according to some examples, the thickness 140 of the MFCs 132a, 132b permits the MFCs 132a, 132b to concentrate more magnetic flux through the Hall sensor 106. For example, with a thickness 140 of approximately 18 μm, an in-plane magnetic field between the MFCs 132a, 132b may be amplified approximately three times relative to no MFC being present. Hence, the increased in-plane magnetic field may effectively result in a higher sensitivity of the Hall sensor 106. By forming the MFCs 132a, 132b over the protective dielectric layer 120 (and further, possibly over the polymer layer 122) as shown in FIG. 1, the thickness 140 of the MFCs 132a, 132b may be much larger, which allows further increase in the concentration of the magnetic flux. The increased concentration of the magnetic flux can offset the increased distance 142 of the MFCs 132a, 132b from the Hall sensor 106. Accordingly, the sensitivity of the Hall sensor 106 can be increased.

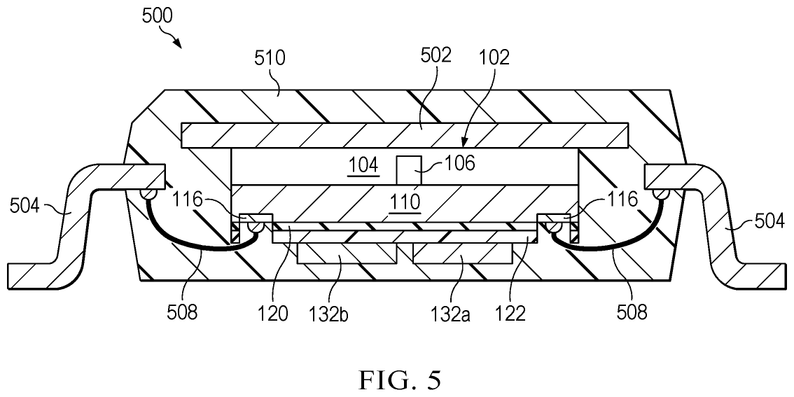

FIG. 5 is a cross-sectional view of a packaged integrated circuit 500 having therein the sensor device 100 of FIG. 1 according to some examples. The packaged integrated circuit 500 includes the semiconductor die 102 of FIG. 1. The semiconductor die 102 is attached or adhered to a leadframe 502. The semiconductor die 102 is shown including the semiconductor substrate 104 (that includes the Hall sensor 106). The semiconductor die 102 also includes the interconnect structure 110 (that includes metal external connector bond pads 116), the protective dielectric layer 120, and the polymer layer 122 on a frontside of the semiconductor substrate 104. A backside of the semiconductor substrate 104 of the semiconductor die 102 is attached or adhered to the leadframe 502. The leadframe 502 includes leads 504. Respective wires 508 are bonded to and between metal external connector bond pads 116 of the semiconductor die 102 and leads 504 of the leadframe 502. A molding compound 510 encapsulates the semiconductor die 102, MFCs 132a, 132b, and wires 508. The molding compound 510 adjoins and encapsulates/covers the polymer layer 122 and the MFCs 132a, 132b. Although the example of FIG. 5 is described in the context of a package 500 using a leadframe and wire bonding, such as for a quad flat package (QFP), small outline package (SOP), or the like, other examples may implement other types of packages.

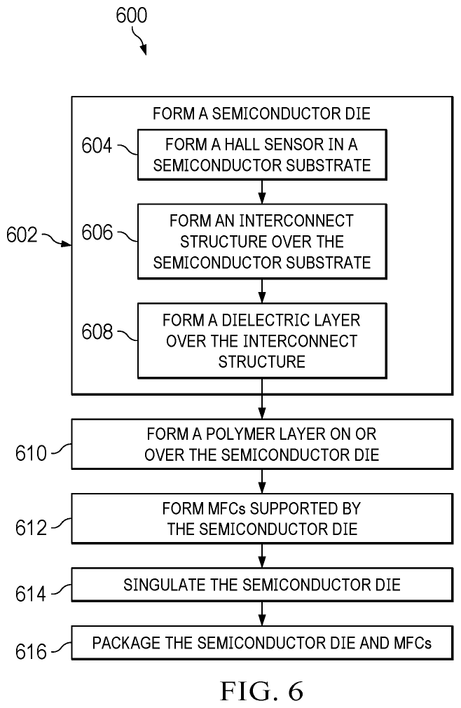

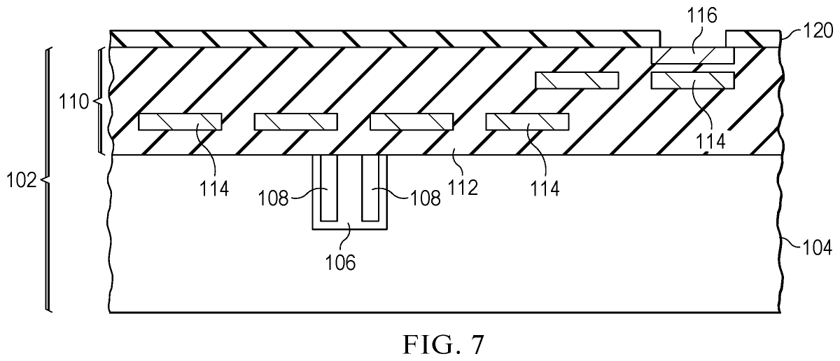

FIG. 6 is a flowchart of a method 600 of fabricating the packaged integrated circuit 500 of FIG. 5, which includes a method of forming the sensor device 100, according to some examples. At block 602, a semiconductor die 102 is formed. The semiconductor die 102 may be formed by, at block 604, forming a Hall sensor 106 in a semiconductor substrate 104; at block 606, forming an interconnect structure 110 over the semiconductor substrate 104; and at block 608, forming a protective dielectric layer 120 over the interconnect structure 110. The Hall sensor 106 may be formed using front-end-of-the-line (FEOL) processing, including dopant implantation, etching, and deposition techniques. The interconnect structure 110 may be formed using back-end-of-the-line (BEOL) processing, including deposition and etching techniques. The protective dielectric layer 120 may be deposited on or over the interconnect structure 110 by a deposition process, such as chemical vapor deposition (CVD) or the like. The protective dielectric layer 120 may be patterned to expose bond pads 116 using photolithography and etching. FIG. 7 illustrates the formation of the semiconductor die 102.

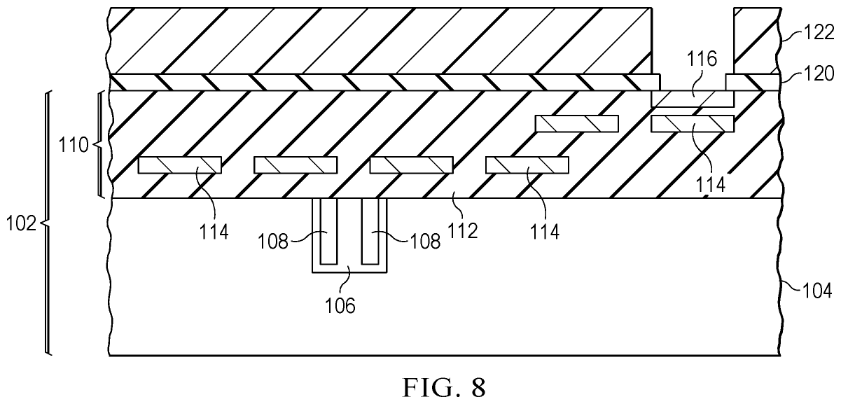

Referring back to FIG. 6, at block 610, a polymer layer 122 is formed on or over the semiconductor die 102 (e.g., on or over the protective dielectric layer 120). FIG. 8 illustrates the polymer layer 122 formed on or over the protective dielectric layer 120. In some examples, such as when the polymer layer 122 is a photosensitive polymer layer, the polymer layer 122 may be formed by spin coating, and the polymer layer 122 may be patterned to expose the bond pads 116 by a photolithography process. Other materials may be implemented for the polymer layer 122, and the polymer layer 122 may be deposited and patterned using other processes. In other examples, the polymer layer 122 may be omitted, and the processing of block 610 and FIG. 8 may likewise be omitted.

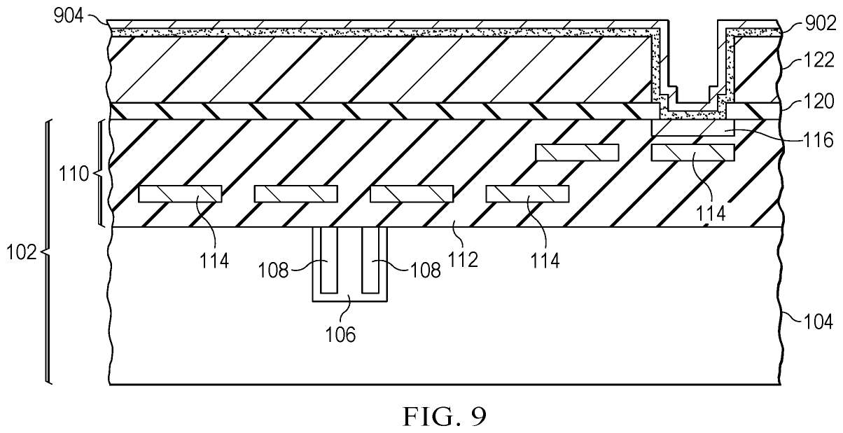

Referring back to FIG. 6, at block 612, MFCs 132a, 132b are formed on the semiconductor die 102. In some examples, the MFCs 132a, 132b are formed on or over the protective dielectric layer 120, and in some examples, the MFCs 132a, 132b are formed on or over the polymer layer 122. FIGS. 9 through 12 are partial cross-sectional views of the sensor device 100 during the formation of the MFCs 132a, 132b according to some examples. The examples illustrated in FIGS. 9 through 12 shows the MFCs 132a, 132b being formed using a plating process (e.g., an electroplating process or electroless plating process). In other examples, the MFCs 132a, 132b can be formed using another process. For example, the MFCs 132a, 132b may be formed as standalone devices, and then the MFCs 132a, 132b can be placed on the semiconductor die 102 using, for example, a pick-and-place process.

Referring to FIG. 9, an adhesion layer 902 is formed on or over the polymer layer 122, and a seed layer 904 is formed on or over the adhesion layer 902. The adhesion layer 902 and the seed layer 904 may be formed by an appropriate deposition process, such as physical vapor deposition (PVD), CVD, atomic layer deposition (ALD), or the like. In some examples, the adhesion layer 902 may be titanium tungsten (TiW), titanium (Ti), titanium nitride (TiN), or the like, and the seed layer 904 may be copper, permalloy (NiFe), or the like. Different materials and deposition processes may be used based on, e.g., the underlying material on which the adhesion layer 902 is deposited and/or the magnetic material of the MFCs 132a, 132b to be implemented.

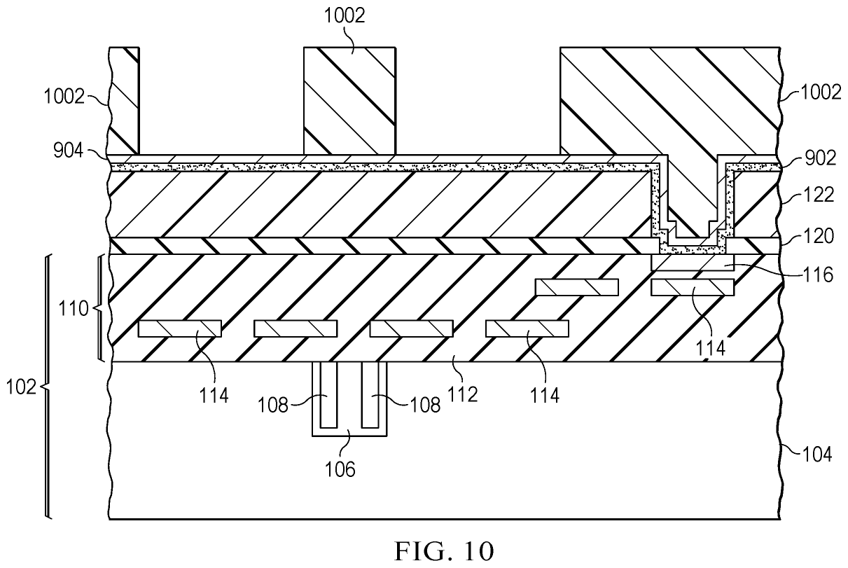

FIG. 10 shows a patterned photoresist 1002 formed on or over the seed layer 904. The patterned photoresist 1002 may be formed by spin coating the photoresist 1002 on or over the seed layer 904 and patterning the photoresist 1002 using photolithography. The patterned photoresist 1002 has openings therethrough exposing the seed layer 904 where the MFCs 132a, 132b are to be located.

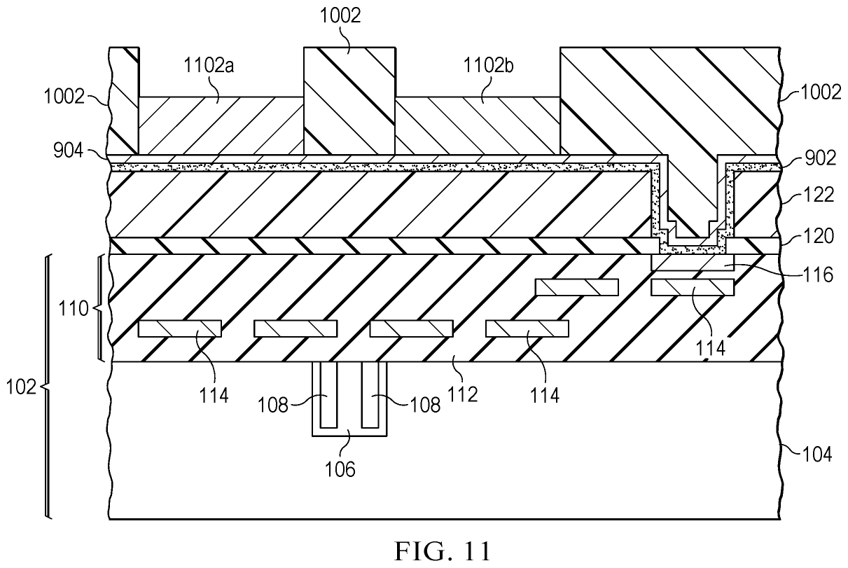

FIG. 11 shows magnetic material 1102a, 1102b formed on the seed layer 904 exposed by the patterned photoresist 1002. The magnetic material 1102a, 1102b may be formed by a plating process, such as electroplating or electroless plating. The magnetic material 1102a, 1102b may be, in some examples, cobalt, nickel, iron, a binary alloy thereof (e.g., nickel iron (NiFe) alloy), and/or a ternary alloy thereof.

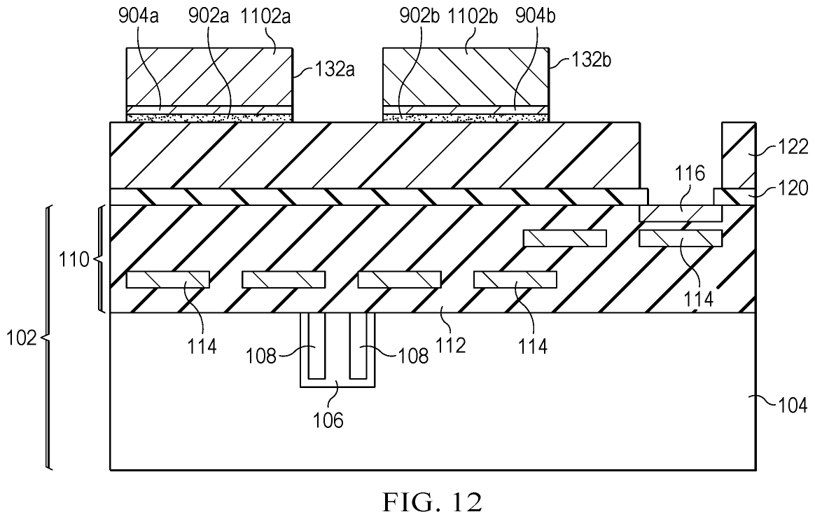

FIG. 12 shows the removal of the patterned photoresist 1002. The patterned photoresist 1002 may be removed using an ash process, a strip process, or the like. With the patterned photoresist 1002 removed, exposed portions of the seed layer 904 and respective underlying portions of the adhesion layer 902 are removed. The portions of the seed layer 904 and adhesion layer 902 that are removed do not underlie the magnetic material 1102a, 1102b. The portions of the seed layer 904 and adhesion layer 902 may be removed using one or more appropriate etch processes, which may be a dry or wet etch, selective to the materials of the seed layer 904 and adhesion layer 902. The MFC 132a, as shown, includes magnetic material 1102a and respective portions of the seed layer 904a and the adhesion layer 902a. The MFC 132b, as shown, includes magnetic material 1102b and respective portions of the seed layer 904b and the adhesion layer 902b.

In some examples, the processing described above with respect to block 602 (e.g., including blocks 604 through 608 (e.g., up to and including the formation of the protective dielectric layer 120)) may be performed in a wafer fabrication facility (“fab”) that performs FEOL and BEOL processing. The processing of block 612, in which the MFCs 132a, 132b are formed, may be performed outside of the wafer fab and in another facility, such as a packaging or assembly facility. By permitting the processing of block 612 to be performed in another facility, such as a packaging or assembly facility, the MFCs 132a, 132b may be formed with a greater thickness 140 than if the MFCs 132a, 132b were formed in the wafer fab by BEOL processing. For example, a packaging or assembly facility may have tools capable of forming the MFCs 132a, 132b to greater thicknesses than tools of a wafer fab.

Referring back to FIG. 6, at block 614, the semiconductor die 102 (with the MFCs 132a, 132b thereover) is singulated. The semiconductor die 102 may be fabricated as part of a larger substrate, such as a wafer. The substrate may include multiple Semiconductor dies that are fabricated simultaneously. At block 614, the semiconductor die 102 is singulated from the remainder of the wafer, such as by sawing or dicing.

At block 616, the semiconductor die 102 (with the MFCs 132a, 132b thereover) is packaged in packaged integrated circuit 500. For example, the semiconductor die 102 may be attached or adhered to a leadframe 502 using a pick-and-place technique. Wires 508 may be bonded to the metal external connector bond pads 116 of the semiconductor die 102 and to the leads 504 of the leadframe 502. A molding compound 510 is then flowed encapsulating the semiconductor die 102, the wires 508, and portions of the leads 504 and leadframe 502. A compression molding technique or the like may be used to apply the molding compound 510.

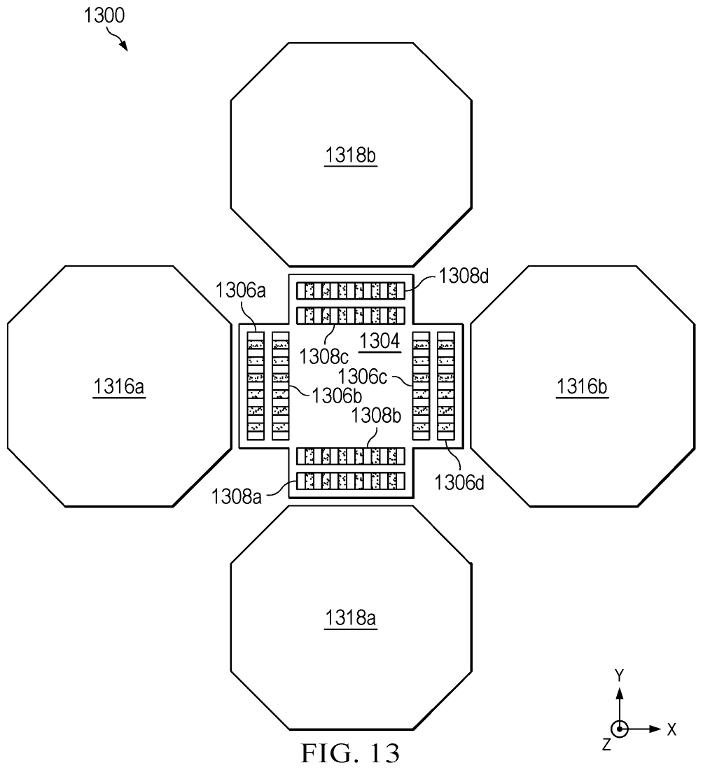

FIG. 13 is a plan view of a sensor device 1300 including a two-dimensional Hall sensor 1304 with MFCs 1316a, 1316b, 1318a, 1318b according to some examples. The layout view of FIG. 13 is in an x-y plane. Although not specifically illustrated, the two-dimensional Hall sensor 1304 is in a semiconductor die, such as semiconductor die 102, and the MFCs 1316a, 1316b, 1318a, 1318b are over or supported by the semiconductor die. Further, the two-dimensional Hall sensor 1304 is in a semiconductor substrate of the semiconductor die, such as the semiconductor substrate 104 described previously. Like described previously, an interconnect structure is on or over the semiconductor substrate; a protective dielectric layer is on or over the interconnect structure; and a polymer layer may be on or over the protective dielectric layer. The MFCs 1316a, 1316b, 1318a, 1318b are on or over the protective dielectric layer or the polymer layer.

The two-dimensional Hall sensor 1304 includes two one-dimensional Hall sensors. A first one-dimensional Hall sensor includes first directional active sensor sub-elements 1306a, 1306b, 1306c, 1306d in the semiconductor substrate, and a second one-dimensional Hall sensor includes second directional active sensor sub-elements 1308a, 1308b, 1308c, 1308d in the semiconductor substrate. Each of the first one-dimensional Hall sensor and the second one-dimensional Hall sensor may have or include a different number of active sensor sub-elements, such as each having two active sensor sub-elements. Each active sensor sub-element 1306a, 1306b, 1306c, 1306d, 1308a, 1308b, 1308c, 1308d may be like the active sensor sub-element 108 illustrated in and described with respect to FIG. 2 or another active sensor sub-element. The first directional active sensor sub-elements 1306a, 1306b, 1306c, 1306d of the first one-dimensional Hall sensor are configured to sense a magnetic field along a first direction, which is an x-direction in FIG. 13, and the second directional active sensor sub-elements 1308a, 1308b, 1308c, 1308d of the second one-dimensional Hall sensor are configured to sense a magnetic field along a second direction perpendicular to the first direction, which is a y-direction in FIG. 13. Each of the one-dimensional Hall sensors of the two-dimensional Hall sensor 1304 may include one or more dummy sensor sub-elements, like described above.

The second directional active sensor sub-elements 1308a, 1308b, 1308c, 1308d are laterally between the first directional active sensor sub-elements 1306a, 1306b and the first directional active sensor sub-elements 1306c, 1306d. The first directional active sensor sub-elements 1306a, 1306b, 1306c, 1306d are laterally between the second directional active sensor sub-elements 1308a, 1308b and the second directional active sensor sub-elements 1308c, 1308d. With the active sensor sub-elements configured and spaced as illustrated, relative sensing of magnetic fields in the first direction and the second direction may be more uniform since the active sensor sub-elements for a given direction are spaced the same as the active sensor sub-elements for the other direction.

At least part of the two-dimensional Hall sensor 1304 is laterally between the MFCs 1316a, 1316b along the first direction. In the illustrated example, each of the MFCs 1316a, 1316b can be laterally offset from a respective nearest boundary of a respective nearest active sensor sub-element of the first one-dimensional Hall sensor of the two-dimensional Hall sensor 1304 (e.g., at the first directional active sensor sub-elements 1306a, 1306d, respectively) by a distance. Like described previously, the MFCs 1316a, 1316b may overlap with one or more dummy sensor sub-elements of the two-dimensional Hall sensor 1304 (not shown in FIG. 13). In other examples, one or both of the MFCs 1316a, 1316b may have a sidewall that vertically aligns with a respective nearest boundary of a respective nearest active sensor sub-element of the two-dimensional Hall sensor 1304, and/or one or both the MFCs 1316a, 1316b may have a portion that vertically overlaps a respective portion of a respective nearest active sensor sub-element of the two-dimensional Hall sensor 1304. The MFCs 1316a, 1316b are therefore configured to concentrate an in-plane (e.g., in an x-y plane) magnetic flux along the first direction through the first one-dimensional Hall sensor (e.g., the first directional active sensor sub-elements 1306a, 1306b, 1306c, 1306d) of the two-dimensional Hall sensor 1304. As oriented, the MFCs 1316a, 1316b concentrate a magnetic flux along an x-direction, and the first one-dimensional Hall sensor (e.g., the first directional active sensor sub-elements 1306a, 1306b, 1306c, 1306d) senses a magnetic field that is along the x-direction.

Further, at least part of the two-dimensional Hall sensor 1304 is laterally between the MFCs 1318a, 1318b along the second direction. In the illustrated example, each of the MFCs 1318a, 1318b is laterally offset from a nearest boundary of the second one-dimensional Hall sensor of the two-dimensional Hall sensor 1304 (e.g., at the second directional active sensor sub-elements 1308a, 1308d, respectively) by a distance. Neither of the MFCs 1318a, 1318b vertically overlap with the second one-dimensional Hall sensor of the two-dimensional Hall sensor 1304 (e.g., no portion of either of the MFCs 1318a, 1318b is directly over and within the boundaries of the second one-dimensional Hall sensor). Like described previously, the MFCs 1316a, 1316b may overlap with one or more dummy sensor sub-elements of the two-dimensional Hall sensor 1304 (not shown in FIG. 13). In other examples, one or both of the MFCs 1318a, 1318b may have a sidewall that vertically aligns with a respective nearest boundary of a respective nearest active sensor sub-element of the two-dimensional Hall sensor 1304, and/or one or both the MFCs 1318a, 1318b may have a portion that vertically overlaps a respective portion of a respective nearest active sensor sub-element of the two-dimensional Hall sensor 1304. The MFCs 1318a, 1318b are therefore configured to concentrate an in-plane (e.g., in an x-y plane) magnetic flux along the second direction through the second one-dimensional Hall sensor (e.g., the second directional active sensor sub-elements 1308a, 1308b, 1308c, 1308d) of the two-dimensional Hall sensor 1304. As oriented, the MFCs 1318a, 1318b concentrate a magnetic flux along a y-direction, and the second one-dimensional Hall sensor (e.g., the second directional active sensor sub-elements 1308a, 1308b, 1308c, 1308d) senses a magnetic field that is along the y-direction.

Other aspects and characteristics of the MFCs 1316a, 1316b, 1318a, 1318b can be understood from the preceding description related to the MFCs 132a, 132b. For example, the MFCs 1316a, 1316b, 1318a, 1318b are shown to be octagonal, and in other examples, the MFCs 1316a, 1316b, 1318a, 1318b may have other lateral shapes, such as circle, rectangle, square, etc. The two-dimensional Hall sensor 1304 is shown as an example. Any number of active sensor sub-elements may be included along any direction of a two-dimensional Hall sensor 1304 in other examples. Further, the active sensor sub-elements may be in other configurations in a two-dimensional Hall sensor 1304 in other examples.

In this description, the term “couple” may cover connections, communications or signal paths that enable a functional relationship consistent with this description. Accordingly, if device A generates a signal to control device B to perform an action, then: (a) in a first example, device A is coupled directly to device B; or (b) in a second example, device A is coupled to device B through intervening component C if intervening component C does not substantially alter the functional relationship between device A and device B, so device B is controlled by device A via the control signal generated by device A.

A device “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or packaged integrated circuit (IC)) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means within +/−10 percent of the stated value, or, if the value is zero, a reasonable range of values around zero. Modifications are possible in the described examples, and other implementations are possible, within the scope of the claims.

What is claimed is:

1. A sensor device comprising:
a semiconductor die including:
a semiconductor substrate including a Hall sensor in a semiconductor material; and
an interconnect structure over the semiconductor substrate;
a first magnetic flux concentrator over the semiconductor die; and
a second magnetic flux concentrator over the semiconductor die, in which at least part of the Hall sensor is laterally between the first magnetic flux concentrator and the second magnetic flux concentrator.

2. The sensor device of claim 1, wherein the first magnetic flux concentrator and the second magnetic flux concentrator are laterally spaced from a respective nearest active sensor element of the Hall sensor.

3. The sensor device of claim 1, wherein:
the interconnect structure includes an interconnect metal layer and a bond pad;
the semiconductor die includes a protective dielectric layer over the interconnect metal layer; and
the first magnetic flux concentrator and the second magnetic flux concentrator are over the protective dielectric layer.

4. The sensor device of claim 3, wherein:
the semiconductor die further includes a polymer layer over the protective dielectric layer; and
the first magnetic flux concentrator and the second magnetic flux concentrator are over the polymer layer.

5. The sensor device of claim 1, wherein the first magnetic flux concentrator and the second magnetic flux concentrator each have a thickness in a direction normal to a top surface of the semiconductor substrate, the thickness being equal to or greater than 10 μm.

6. The sensor device of claim 1, wherein the first magnetic flux concentrator and the second magnetic flux concentrator are of a vertical distance in a range from 5 μm to 100 μm from a top surface of the semiconductor substrate.

7. The sensor device of claim 1, wherein the first magnetic flux concentrator includes cobalt, nickel, iron, a binary alloy thereof, or a ternary alloy thereof.

8. The sensor device of claim 1, further comprising:
a third magnetic flux concentrator over the semiconductor die; and
a fourth magnetic flux concentrator over the semiconductor die,
wherein:
the Halls sensor is a first Hall sensor;
the first Hall sensor is laterally between the first magnetic flux concentrator and the second magnetic flux concentrator along a first lateral direction;
the semiconductor substrate includes a second Hall sensor in the semiconductor material;
the second Hall sensor is laterally between the third magnetic flux concentrator and the fourth magnetic flux concentrator along a second lateral direction; and
the first lateral direction is perpendicular to the second lateral direction.

9. An integrated circuit comprising:
a semiconductor die including a Hall sensor;
a first magnetic flux concentrator on the semiconductor die;
a second magnetic flux concentrator on the semiconductor die, in which at least part of the Hall sensor is laterally between the first magnetic flux concentrator and the second magnetic flux concentrator; and
a molding compound that encapsulates the semiconductor die, the first magnetic flux concentrator, and the second magnetic flux concentrator.

10. The integrated circuit of claim 9, wherein the semiconductor die includes:
a semiconductor substrate including the Hall sensor;
an interconnect structure over the semiconductor substrate, the interconnect structure including an interconnect metal layer; and
a protective dielectric layer over the interconnect metal layer, wherein the first magnetic flux concentrator and the second magnetic flux concentrator are over the protective dielectric layer.

11. The integrated circuit of claim 10, wherein the semiconductor die includes a polymer layer over the protective dielectric layer; and
wherein the first magnetic flux concentrator and the second magnetic flux concentrator are on the polymer layer, and the molding compound covers the polymer layer.

12. The integrated circuit of claim 10, further comprising:
a third magnetic flux concentrator over the semiconductor die; and
a fourth magnetic flux concentrator over the semiconductor die,
wherein:
the Halls sensor is a first Hall sensor;
the first Hall sensor is laterally between the first magnetic flux concentrator and the second magnetic flux concentrator along a first lateral direction;
the semiconductor substrate includes a second Hall sensor;
the second Hall sensor is laterally between the third magnetic flux concentrator and the fourth magnetic flux concentrator along a second lateral direction;
the first lateral direction is perpendicular to the second lateral direction; and
the molding compound encapsulates the third magnetic flux concentrator and the fourth magnetic flux concentrator.

13. The integrated circuit of claim 9, wherein the first magnetic flux concentrator and the second magnetic flux concentrator each have a thickness equal to or greater than 10 μm.

14. The integrated circuit of claim 9, wherein the first magnetic flux concentrator and the second magnetic flux concentrator each are laterally offset from a respective nearest active sensor element of the Hall sensor.

15. A method comprising:
forming a first magnetic flux concentrator on a semiconductor die including a Hall sensor;
forming a second magnetic flux concentrator on the semiconductor die, so that at least part of the Hall sensor is laterally between the first magnetic flux concentrator and the second magnetic flux concentrator; and
packaging the semiconductor die and the first and second magnetic flux concentrators to form an integrated circuit.

16. The method of claim 15, further comprising:
forming the Hall sensor in a semiconductor substrate;
forming an interconnect structure over the semiconductor substrate, the interconnect structure including a metal layer that includes an external connector bond pad; and
forming a protective dielectric layer over the interconnect structure, wherein the first magnetic flux concentrator and the second magnetic flux concentrator are over the protective dielectric layer.

17. The method of claim 16, further comprising forming a polymer layer over the protective dielectric layer, in which the first magnetic flux concentrator and the second magnetic flux concentrator are over the polymer layer.

18. The method of claim 15, wherein forming the first magnetic flux concentrator and the second magnetic flux concentrator are formed by a respective electroplating process.

19. The method of claim 15, wherein packaging the semiconductor die, the first magnetic flux concentrator, and the second magnetic flux concentrator includes encapsulating the semiconductor die, the first magnetic flux concentrator, and the second magnetic flux concentrator with a molding compound.

20. The method of claim 15, wherein the first magnetic flux concentrator and the second magnetic flux concentrator each have a thickness equal to or greater than 10 μm.
